(19) United States
(12) Patent Application Publication
(10) Pub. No.: US 2026/0044256 A1
(43) Pub. Date: Feb. 12, 2026

(54) INTERACTIVE DISPLAY OF ELECTRICAL PROPERTIES OF AN ELECTRICAL COMPONENT

(71) Applicant: NEXPERIA B.V., Nijmegen (NL)

(72) Inventors: Stein Hans Nesbakk, Manchester (GB); Georgii Iashin, Stockport (GB)

(73) Assignee: NEXPERIA B.V., Nijmegen (NL)

(21) Appl. No.: 19/361,327

(22) Filed: Oct. 17, 2025

Related U.S. Application Data
(63) Continuation of application No. PCT/IB2024/000190, filed on Apr. 18, 2024.
(60) Provisional application No. 63/497,057, filed on Apr. 19, 2023.

(51) Int. Cl. G06F 3/04847; G06F 30/367

(52) U.S. Cl. CPC G06F 3/04847; G06F 30/367

(57) ABSTRACT

A graphical user interface is provided which enables a user to interact with it and obtain information about an electronic component. The graphical user interface allows the user to modify one or more operating conditions of the electronic component, and, following the modification, displays a parameter value applicable in the case of the modified operating conditions. The graphical user interface also associates technical information with parameters of the electrical component so that if a user indicates the parameter on the graphical user interface, the technical information is displayed. The graphical user interface also associates pins of the electrical component with pins on corresponding representations of the electrical component. If a user selects one of the pins on a representation of the electrical component on the graphical user interface, then the same associated pin on other representations is highlighted.

### CROSS REFERENCE TO RELATED APPLICATIONS

This application is a continuation of International Application No. PCT/IB20241/000190 filed on Apr. 18, 2024, which claims priority from U.S. Provisional Application No. 63/497,057 filed on Apr. 19, 2023, the contents of each of which are incorporated by reference herein in its entirety.

### BACKGROUND

### 1. Field of the Disclosure

The present disclosure relates to a computer implemented method for interactively displaying electrical properties of at least one electrical component as well as an information processing apparatus for performing the method and a computer-readable storage medium containing instructions for instructing the information processing apparatus to perform the method. The present disclosure further relates to a computer implemented method for providing technical information relating to an electrical component and a computer-readable storage medium containing corresponding instructions. Finally, the present disclosure relates to a computer implemented method for identifying corresponding electrical component information in response to a received user input and a computer-readable storage medium containing corresponding instructions.

### 2. Description of the Related Art

Electrical components such as metal-oxide-semiconductor field-effect transistors (MOSFETs) have multiple terminals (pins) through which a voltage can be applied, such as a gate, a body, a source, and a drain. Typically, the voltage across the gate and the source terminal dictate the conductivity between the source and the drain terminal. Various parameters (operating conditions) influence the behavior of a MOSFET, and conventionally one or more MOSFETs are measured in physical circuits to compile data for the various operating conditions experienced by the MOSFET. Datasheets can then be prepared to present summaries of the measured data of the one or more MOSFETs, and models such as spice models can be made using the measured data from the one or more MOSFETs to predict the behavior of the MOSFETs in other operating conditions. The behavior of a MOSFET within a circuit can then be simulated with the models before a circuit is assembled to predict how it will function in the circuit. This datasheet is often sent, e.g. as a pdf file, to a user who is considering ordering the MOSFET, or supplied to a user with the MOSFET, so that the user can construct a circuit including the MOSFET using the data.

FIG. 1 shows an example of the datasheet. The electronic component has various parameters. These are listed in the column “parameters”, and a corresponding symbol for each is in the column “symbol”. The column “unit” specifies which unit is used to measure the corresponding parameter. Each of the parameters is associated with one or more operating conditions listed in the column “conditions”. These are operating conditions of the electronic component. The columns “min”, “typ”, “max” give respectively minimum, typical and maximum values for the parameter, given the operating conditions. For example, when the operating conditions are in the range 25° C. to 175° C., a voltage Vos applied between the drain and source pins of the MOSFET should be no more than a maximum of 100 volts. The “conditions” are thus both operating conditions, and also in a sense logical conditions, i.e. conditions which have to be true for the data in the columns “min”, “typ”, and “max” to be reliable. The value of each “parameter” given the corresponding operating conditions may be calculated by simulating the MOSFET under different conditions using, for example, MOSFET spice models. For example, as shown in FIG. 1, total power dissipation (Pₜₒₜ) is calculated as having a maximum value of 341 W assuming a mounting base temperature (T_{mb})=25° C.

Typically the values in the datasheet are a discrete subset of the infinite possibilities of operating conditions (“drive conditions”), so if a user wants to know the value of a parameter at operating conditions not included on the sheet, they must either manually calculate the parameter, or estimate the parameter from one of the accompanying graphs (such as the one linked to as “FIG. 1”) in the row for parameter Pₜₒₜ.

An additional problem with datasheets is that they assume a certain level of understanding of the parameters of the electronic component, which make them hard to use for inexperienced users. For example, the definition of, or relationship between, the parameter(s) may be unclear. Considering the datasheet of FIG. 1, the parameter R_{DSon} is named as the drain-source on-state resistance, a term which not all users will understand. If multiple datasheets have different respective authors, they may use different abbreviations or names to represent parameters. It can even be time-consuming for the user to identify the pins of a physical electrical component to which the data on a datasheet corresponds, and without spending this time the user may misunderstand the properties of the component.

### SUMMARY

The present disclosure provides a computer implemented method for interactively displaying information about an electrical component, an information processing apparatus for performing the method, and a computer-readable storage medium containing instructions for instructing the information processing apparatus to perform the method.

In general terms, a first aspect of the present disclosure proposes a graphical user interface which enables a user to interact with it to modify one or more operating conditions in the datasheet, and which, following the modification of the operating conditions, displays a parameter value applicable in the case of the modified operating conditions. This allows the parameter values to be obtained without having to perform additional calculations or look at graphs.

A second aspect of the present disclosure proposes that a graphical user interface associates technical information with parameters of the electrical component so that if a user indicates the parameter on the graphical user interface, the technical information is displayed. This may include an explanation of the meaning of the parameter, and/or how it is affected by the operating conditions.

A third aspect of the present disclosure proposes a graphical user interface associating the pins of the electrical component with pins on corresponding representations of the electrical component. If a user selects one of the pins on a representation of the electrical component on the graphical user interface, then the same associated pin on other representations will also be identified (graphically highlighted).

Any one or more of the above aspects of the present disclosure may be freely combined in a single graphical user interface, which provides a product for understanding the operation and usage conditions of an electronic component. The graphical user interface may be supplied to a user, for example in the form of a computer program product containing program instructions operative, when implemented by the processor of a computer system, to generate the graphical user interface, and including databases of technical information employed by the program instructions. The user may be a user who is considering ordering the electrical component or is designing an electronic circuit. Alternatively, the computer program product may be supplied to a user who already has the electrical component (e.g. supplied with the electrical component), so that the user can construct a circuit including the electrical component using information obtained from the graphical user interface.

Thus, the present disclosure provides a way of designing and/or constructing an electronic circuit which comprises obtaining information about an electronic component using a graphical user interface as described above, and based on the information forming a design for an electronic circuit comprising the electronic component (e.g. based on the information, selecting one or more other electronic components of the electronic circuit and/or locations of the electronic components of the electronic circuit and/or locations of conductive pathways of the electronic circuit), and optionally physically constructing the electronic circuit based on the design.

### BRIEF DESCRIPTION OF DRAWINGS

Non-limiting examples of the present disclosure will now be described for the sake of example only, with reference to the following drawings in which:

FIG. 1 shows a known datasheet of parameters and their values for a MOSFET.

FIG. 2A shows a display generated by a graphical user interface during an operation of modifying a parameter in an embodiment of the present disclosure.

FIG. 2B shows the display of FIG. 2A after parameters have been modified by a user.

FIG. 3A shows the display of FIG. 2A with technical information displayed alongside a corresponding parameter.

FIG. 3B shows the display of FIG. 2A, with technical information displayed alongside a corresponding parameter that is different to the corresponding parameter in FIG. 3A.

FIG. 4 shows portion of a display identifying various pins of a MOSFET in the graphical user interface of FIG. 2A.

FIG. 5 is a flow diagram of a first method which is an embodiment of the disclosure.

FIG. 6 is a flow diagram of a second method which is an embodiment of the disclosure.

FIG. 7 is a flow diagram of a third method which is an embodiment of the disclosure.

### DETAILED DESCRIPTION

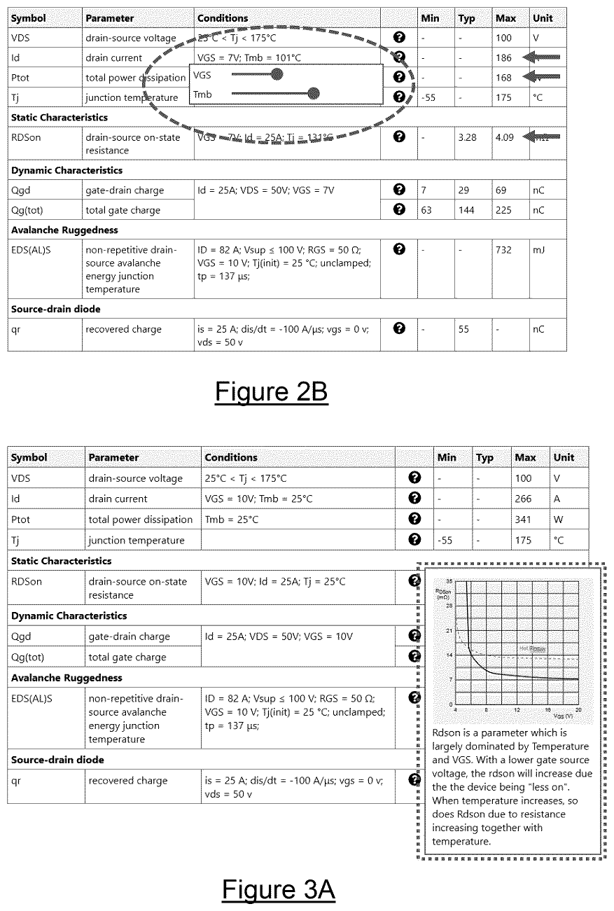

A computer implemented method for interactive display of electrical properties of an electrical component which is an embodiment of the present disclosure will now be described with reference to FIGS. 2A and 2B. By “electrical component” is meant at least one electronic element with a plurality of conductive terminals (“pins”) for transmitting electrical signals into or out of the component. Examples of suitable electronic components include any of bipolar transistors, diodes, ESD (electrostatic discharge) protection elements, transient voltage suppressors, signal conditioning elements, MOSFETs (metal oxide semiconductor field effect transistors), GaN FETs (gallium nitride field effect transistors), analog and logic ICs (integrated circuits), IGBTs (insulated-gate bipolar transistors). The term “electronic component” further includes components defined by their function, such as amplifiers, comparators, attenuators, controllers, drivers, interfaces, switches, memory, microcontrollers, processors, multimedia, power management, and lighting elements. An “electronic component” is typically a one-piece electronic element, but in some cases multiple one-piece units configured to operate together to form an electronic component such as a power module or a motor drive unit. The electronic components above are components having variable parameters, but some electronic components with pins do not, such as bulbs, plugs and connectors.

The embodiment is a graphical user interface (GUI) which is presented to a user by a computer system operated by the user. The computer system includes a processor, a display device controlled by the processor, and one or more data input devices, such as pointer devices (e.g. a computer mouse) or a touch-sensitive screen. The GUI may for example be generated by a computer-program product which is supplied to the computer system as an app (e.g. downloaded over a communications system such as the internet). The product may be supplied by the manufacturer of electrical components. Optionally, it may be supplied with the electrical component(s), e.g. on a tangible recording medium which is supplied with the components. Alternatively, it may be downloadable separately, e.g. by a user who is considering ordering, or who has ordered or obtained, one of the electrical components.

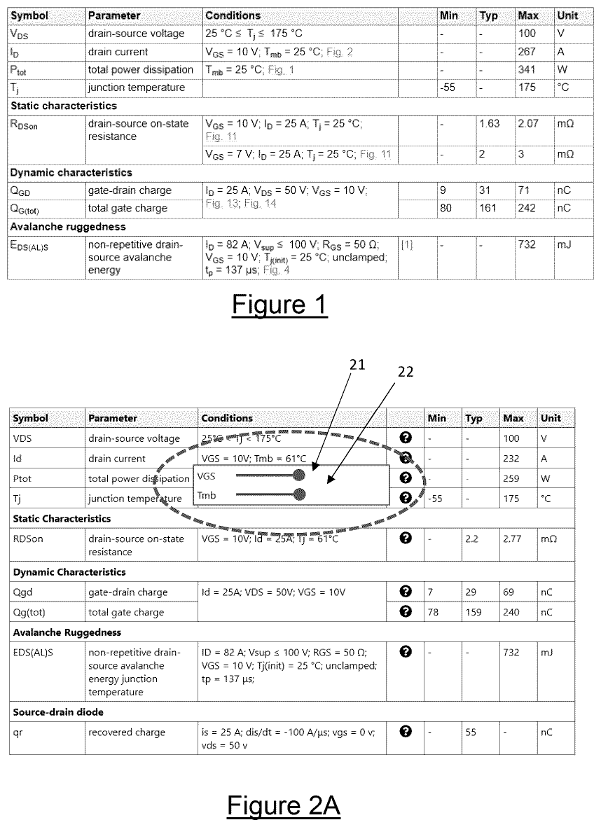

The initial appearance of a display generated by the GUI may be generally similar to the fixed datasheet shown in FIG. 1, particularly if the electrical component is a MOSFET, but in variations of the embodiment the GUI may give information for a different electronic component. As explained above, the electronic component has various parameters which may be listed in a column “Parameter”, with a corresponding symbol for each in the column “symbol”. The column “unit” specifies which unit is used to measure the corresponding parameter. Each of the parameters is associated with one or more other parameters listed in the column “conditions”. These are operating conditions of the electronic component. The columns “min”, “typ”, “max” give respectively minimum, typical, and maximum values for the parameters, given the operating conditions. In the description below the “conditions” are referred to as “first parameters”, upon which the “second parameters” (the ones listed in the column “parameter”) depend. The first parameters may be considered as input parameter values of the electronic component, whereas the second parameters may be considered as consequent output parameter values. For example, the second parameter “drain current”, I_{D}, may be shown in a display generated by the GUI and resembling FIG. 1 as dependent upon two first parameters, the voltage Vos between the gate and the source, and the mounting base temperature T_{mb}.

In contrast to the known data-sheet described above, the user may select a field for one of the first parameters which specifies the corresponding conditions using a data input device of the computer system. Selecting the field causes at least one data input element to be displayed for one or more of the first conditions. For example, FIG. 2A shows a display generated by the GUI which is an embodiment of the present disclosure once the user has selected the box for the parameters (conditions) in the row corresponding to the drain current (I_{D}). In this case, the data input elements are slider bars 21, 22. An initial value for V_{GS} is 10V and an initial temperature of the device T_{mb} is 61° C. Corresponding initial maximum values for the second parameters Pₜₒₜ and I_{D} are 259W and 232A respectively. The user has the choice to modify the value of either Ves or T_{mb}, neither of them, or both of them, using the respective slider bars 21, 22 for the two second parameters.

As shown in FIG. 2B, the GUI receives from the user the value of at least one first parameter which characterizes an operating condition of the electrical component. Specifically, as shown in FIG. 2B, the user has selected the condition (first parameter) V_{GS} and modified the initial value to be 7V, and selected the condition (first parameter) T_{mb}, and modified the initial value to be 101° C. Each of these modifications is made using the respective slider control (e.g. operated by a mouse or, if the screen is touch sensitive, the user's finger) to enter the respective desired value. The method of input is not limited and for example, could be a field for a user to manually enter a desired value such as by typing.

By implementing program instructions associated with the GUI, the computer system obtains (e.g. calculates, as described below) a value of a second parameter (e.g. in the example, the second parameter I_{D}) that is indicative of an electrical property of the MOSFET when operated according to the operating condition(s) specified by the at least one parameter received.

In one case, the computer system may calculate the value of the at least one second parameter using the modified first parameter(s) (and any first parameter(s) which were not modified) by simulating the MOSFET in a circuit under those operating conditions. Alternatively, the value of the at least one second parameter may be extracted from another source, such as a spice model, or from a database. The database could be provided with the interactive datasheet, or made available on the cloud.

In the example of FIG. 2B, as a result of the modifications to Vos and T_{mb}, the value of I_{d} which is displayed to the user, changes, as it depends on both Ves and T_{mb}. Furthermore, it can be seen in FIG. 2B that because Pₜₒₜ also depends on T_{mb}, while drain-source on-state resistance (R_{DSon}) depends on I_{D}, the values of Pₜₒₜ and R_{DSon} also change.

In the above, Vos and T_{mb} are both called “first parameters” while Ip was a “second parameter” with respect to them. While in the example, the values of two first parameters were changed, this is not essential, and the user could instead have modified only Vos or only T_{mb} had they so desired. Another way of describing the above steps is that a user inputs via the GUI a change to the value of at least one first parameter, and as a result a corresponding value of at least one second parameter which is associated with the modified value of the first parameter is displayed.

The calculation performed to calculate the modified value of the second parameter(s) can be performed after the user inputs the modified value of the first parameter(s), for example using a MOSFET spice model.

Alternatively, since this may be time-consuming, respective values for the second parameter(s) for each of multiple possible choices for the first parameter(s) may be calculated in advance and stored. The possible choices for the first parameter(s) are referred to as “additional values” of the first parameter, and the corresponding values of the second parameter(s) calculated using the additional values of the first parameter(s) are referred to as “additional values” of the second parameter(s).

If the user inputs a modified value of at least one first parameter via the GUI that is the same as one of the additional values of the first parameter, the calculated additional value of the second parameter that corresponds to the generated additional value of the first parameter may be extracted from the store and displayed.

Alternatively, if the user inputs a modified value of a first parameter via a GUI which is not the same as one of the generated additional values of the first parameter, then the value of the second parameter indicative of an electrical property of the MOSFET when operated according to the operating condition specified by the modified value of the first parameter is calculated.

The value of the second parameter that is indicative of an electrical property of the MOSFET when operated according to the operating condition specified by the modified value of the first parameter can be calculated using MOSFET spice models.

Alternatively, the value of the second parameter can be calculated using interpolation algorithms based on the additional values of the first and second parameter(s).

For example, consider the case in which there is only a single first parameter and a single second parameter which depends on it. The additional values of the first parameter may be considered as an ordered sequence, which we might denote {xᵢ} for i=1, . . . n where integer n is the number of additional values of the first parameter. The corresponding additional values of the second parameter may be denoted {yᵢ} for i=1, . . . n. If the value of the modified value of the first parameter, which we might denote xₘ, lies between two of the additional values of the first parameter (say xⱼ and xⱼ₊₁, where j is an integer in the range 1 to n−1), such that xₘ=axⱼ+(a−1)xⱼ₊₁ for some real value a, then the value of the second parameter yₘ corresponding to the modified first parameter xₘ may be taken as yₘ=ayⱼ+(a−1)yⱼ₊₁. In other embodiments, other, more sophisticated interpolation methods may be used, for example, ones which allow interpolation in the case that there are multiple first parameters.

The MOSFET spice models and interpolation algorithms that can be used to calculate the value of the second parameter(s) can be run locally, i.e. on the user computer which displays the GUI, or on a server with which the user computer can communicate over a data communication network.

Taking a look again at the example of FIGS. 2A and 2B, two parameters (V_{GS} and T_{mb}) are modified. However, unless the two parameters are modified simultaneously, there will be a period during which either Ves is modified while T_{mb} is not, or in which T_{mb} is modified while Ves is not. In such a scenario, the value of the second parameter, e.g. the updated value of I_{d}, may be displayed as soon either of the two parameters (both of which are first parameters with respect to I_{d}) is modified. The advantage of displaying the value of the second parameter corresponding to the modified value of a first parameter as soon as the user modifies it is that the user is better informed about how his or her modification of the value of the first parameter affects the value of the second parameter. Alternatively, the modified value of the second parameter may not be displayed until all of the values of both the first parameters in the same field are modified, or an execution instruction is received from the user (e.g. the user clicks a button). The advantage of waiting for all of the values of the first parameters (in this example, V_{GS} and T_{mb}) to be modified or an execution instruction to be received is that less computational resources are required, as only a final value is shown. Additionally, the user is less likely to be overwhelmed by seeing multiple values for the second parameter in quick succession.

The first parameter(s) can be any parameter upon which a second parameter depends. For example, in the context of MOSFETs, the first parameter(s) can be any one or more of: junction temperature (Tⱼ), gate-source voltage (V_{GS}), mounting base temperature (T_{mb}), drain current (I_{D}), drain-source voltage (VDS), gate-source voltage (V_{GS}), supply voltage (Vₛᵤₚ), gate-source resistance (R_{GS}), pulse duration (tₚ), and source-drain current (Iₛ).

The second parameter(s) can be any parameter which changes due to changes in another parameter. For example, in the context of MOSFETs, the second parameter(s) can be any one or more of: drain-source voltage (V_{DS}), drain current (I_{D}), threshold voltages, drainage leakages, total power dissipation (Pₜₒₜ), junction temperature (Tⱼ), drain-source on-state resistance (R_{DSon}), gate-drain charge (Q_{GD}), total gate charge (Q_{G(tot)}), non-repetitive drain-source avalanche energy (E_{DS(AL)S}), recovered charge (Qᵣ), and drain-gate voltage (V_{DGR}). Neither of these lists are comprehensive and other conditions and parameters for a MOSFET could belong to either category.

As suggested by the definition of a first and second parameter, the lists are not mutually exclusive. For example, from FIG. 1, it can be seen that while drain-source voltage is a second parameter with respect to junction temperature, it is a first parameter with respect to gate-drain charge. In other words, the drain-source voltage varies as the junction temperature is modified, and the gate-drain charge varies as the drain-source voltage is modified.

As described, a user can input a modification to the value of a first parameter via the GUI and the calculated value of a second parameter corresponding to the modified first parameter can be displayed. The user is therefore able to obtain values of the second parameters beyond those shown on a fixed datasheet without having to perform manual calculations or graphical analysis. Additionally, the calculated value of a second parameter corresponding to the modified first parameter can be displayed to the user in a variety of ways. For example, the calculated value of a second parameter corresponding to the changed first parameter can be output as a static PDF containing a table like in FIG. 1, but with the relevant parameters updated. Alternatively, said updated table could be presented on a static webpage or a dynamic for the user to view.

As noted above, the fixed datasheet of FIG. 1 may be hard to interpret. In one form, the present GUI addresses this, by associating technical information with each of the parameters of the MOSFET, and displaying the associated technical information on the GUI when a user selects the parameter.

The technical information on one or more parameters in a datasheet can be added by either the original author of the datasheet, or subsequently by someone else. This technical information may, for example, be an explanation of the meaning of the parameter, and/or how it is affected by the operating conditions.

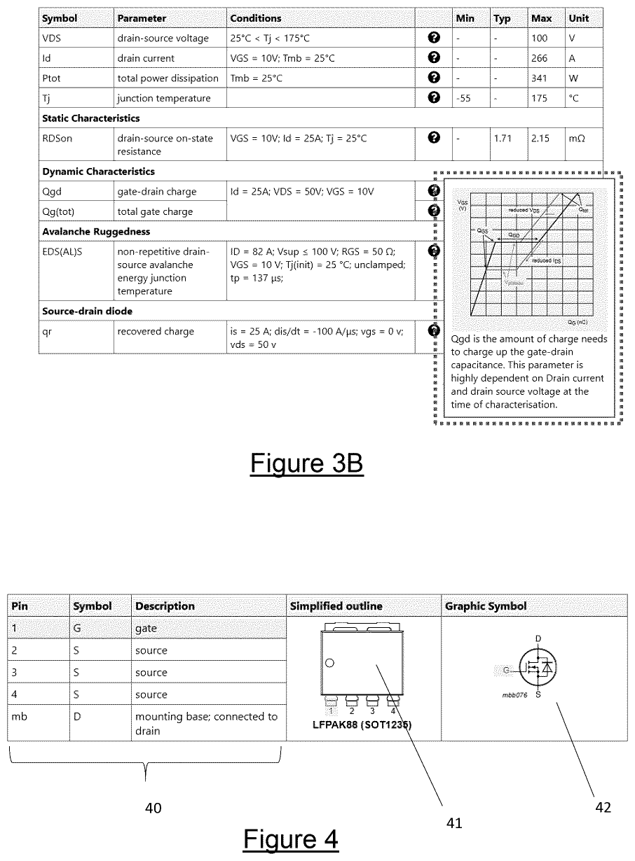

FIG. 3A shows the technical information which is displayed if the user selects the drain-source on-state resistance parameter R_{Dson}. If the user wants to learn more about the drain-source on-state resistance, then, starting from a time in which the GUI is in an initial state which has an appearance resembling FIG. 1, they could use the GUI to select or highlight the parameter, e.g. by moving a pointing device to choose the location where the word “R_{DSon}” is displayed, or performing a “right click” operation when the pointing device is indicating a position in that row. After R_{DSon} is selected or highlighted, the technical information associated with the parameter is displayed on the GUI for the user to view, as shown in FIG. 3A. In this example, the technical information includes both graphical information and written information; however, the technical information could alternatively only include graphical information, or only include written information.

FIG. 3B shows another example in which there is technical information associated with the gate-drain charge parameter Q_{gd} and the user has selected or highlighted Q_{gd} on the GUI. This time, technical information relating to the gate-drain charge parameter Q_{gd} is displayed on the GUI for the user to view. If there is technical information associated with multiple parameters and a user selects one of the parameters for which technical information is stored, followed by selecting another of those parameters, when the second parameter is selected, the technical information associated with the first parameter is no longer be displayed on the GUI. Instead, the technical information associated with the second parameter will be displayed. If the user selects a parameter for which there is no technical information stored, any technical information already displayed on the GUI may no longer be displayed to prevent confusion as to which parameter the technical information is associated with.

Some fixed datasheets include information regarding the pins of an electrical component such as a MOSFET. For example, the information may identify which pins are source pins, drain pins, or gate pins. However, while a user may be able to determine from the datasheet how many source pins or the like there are in a MOSFET, it does not help them identify the role of each individual pin. Additionally, MOSFETs can vary from one to the next, so the layout of pins on one MOSFET may not be the same as the layout of pins on another. To address this, the present GUI can be operated to present information about the pins of an electrical component, e.g. a MOSFET. In particular, the GUI may display one or more graphical representations of an electrical component (e.g. a MOSFET) alongside a representation in the form of a table which lists the pins. This is referred to as “pinning information”. The representations of the MOSFET can be a simplified outline of the MOSFET, or a graphic symbol of the MOSFET such as a circuit diagram. At least one of the pins for which there is pinning information is then associated with the corresponding pin that is displayed in the two or more representations of the MOSFET. When a user selects a pin that is associated with the corresponding pin in the representations (e.g. by using a pointer device, or a finger on a touch-sensitive screen, to select a location corresponding to a pin in any of the representations), the image displayed by the GUI is modified to indicate to the user the corresponding pin in all the other representation(s).

FIG. 4 shows an example of a part of display presented by the present GUI in which pins have pinning information identifying them as a gate, source, or mounting base that is connected to the drain (other information could also be displayed for each pin). This information is shown as data in a table 40. The table has three columns “pin”, “symbol” and “description”. Two graphical representations 41, 42 of the MOSFET are shown adjacent to the pinning information. When a user selects the pin from the pinning information on the GUI, the corresponding pin in the representations 41, 42 is identified to the user. Similarly, if a user selects a pin on one of the representations 41, 42 of the MOSFET, the associated pin from the other representation and in the pinning information 40 is identified to the user.

In either case, the indication may be as shown in FIG. 4 in which “pin 1” of the electrical component has been selected (using any one of the pinning information 40 or the graphical representations 41, 42) causing that pin to be highlighted in the pinning information 40 and the graphical representations 40, 41. While in FIG. 4, the associated pins are identified by being graphically highlighted, they can be identified in other ways, such as by being emboldened, or circled.

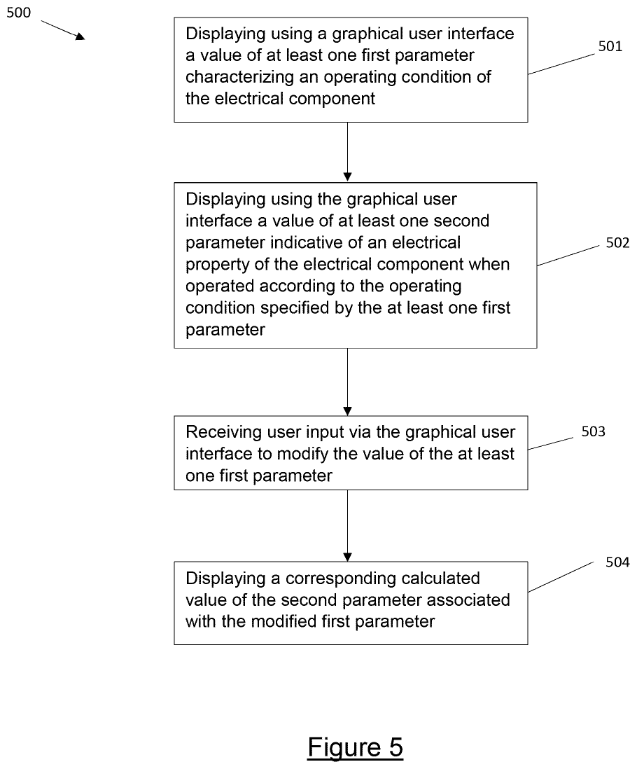

FIG. 5 shows the steps of a first method 500 which is an embodiment of the invention. In step 501 a GUI is used to display the value of at least one first parameter, and in step 502 the GUI is used to display the value of at least one second parameter. These two steps may be performed by a GUI which generates a display having the same general appearance as the fixed datasheet of FIG. 1.

In step 503, as illustrated in FIG. 2A and FIG. 2B, user input is received via the GUI to modify the value of the at least one first parameter.

In step 504, as illustrated in FIG. 2B, a corresponding calculated value of the second parameter associated with the modified first parameter (i.e. the second parameter when calculated using the modified first parameter) is displayed.

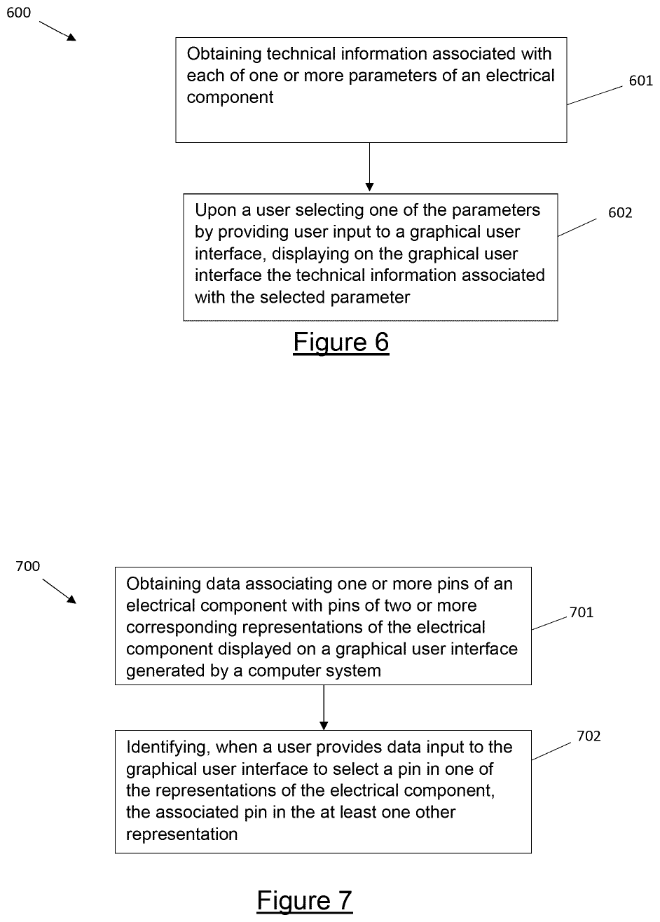

FIG. 6 shows the steps of a second method 600 which is an embodiment of the present disclosure.

In step 601, technical information associated with each of one or more parameters of an electrical component is obtained. For example, the data may be obtained from a database portion of a computer program product which stores program instructions to implement the GUI.

In step 602, upon a user selecting one of the parameters by providing user input to a GUI, the GUI displays the technical information associated with the selected parameter.

FIG. 7 shows the steps of a third method 700 which is an embodiment of the disclosure.

In step 701, data is obtained which associates one or more pins of an electrical component with pins of two or more corresponding representations of the electrical component displayed on a GUI generated by a computer system. For example, the data may be obtained from a database portion of a computer program product which stores program instructions to implement the GUI.

In step 702, upon a user providing data input to the GUI to select a pin in one of the representations of the electrical component, the display generated by the GUI is modified to identify the associated pin in the at least one other representation, e.g. by highlighting.

The GUI can be implemented as program code implemented by a computer system having a processor operative to run the code, and a display device under the control of the processor. The GUI is operative to perform any one or more of the methods 500, 600 and/or 600. The GUI may be programmed using HTML, CSS, or JavaScript, or any other programming language may be used.

With the above disclosure, an interactive datasheet is provided as a GUI that enables a user to dynamically modify operating parameters of a MOSFET or other electronic component or determine information about said parameters. The user can also identify associated pins of a MOSFET between representations of the MOSFET and the pinning information on a datasheet. These capabilities can be implemented individually, or in any combination on a single datasheet.

What is claimed is:

1. A computer-implemented method for interactive display of electrical properties of at least one electrical component, the method comprising:
displaying using a graphical user interface and a value of at least one first parameter characterizing an operating condition of the electrical component;
displaying using the graphical user interface and a value of at least one second parameter indicative of an electrical property of the electrical component when operated according to the operating condition specified by the at least one first parameter;
receiving user input via the graphical user interface to modify the value of the at least one first parameter; and
displaying a corresponding calculated value of the second parameter associated with the modified first parameter.

2. The method of claim 1, further comprising:
prior to receiving the user input:
(i) generating additional values of the at least one first parameter; and
(ii) calculating additional values of the second parameter for each of the generated additional values of the first parameter; and
upon the modified value for the at least one first parameter being one of the additional values of the at least one first parameter, displaying the corresponding additional value of the second parameter.

3. The method of claim 2, further comprising, upon the modified value of the first parameter not being one of the additional values of the first parameter, calculating and displaying a value of the at least one second parameter for the modified value of the at least one first parameter.

4. The method of claim 3, wherein the value of the at least one second parameter for the modified value of the at least one first parameter is calculated by interpolation using the additional values of the first and second parameters.

5. The method of claim 1, wherein the value of the second parameter associated with the modified value of the first parameter is calculated using a MOSFET spice model.

6. The method of claim 1, wherein the at least one of the first parameters of the electrical component comprises at least one of:
a gate-source voltage, and
a mounting base temperature (T_{mb}).

7. The method of claim 1, wherein the second parameter of the electrical component is the drain-source on-state resistance.

8. A computer implemented method of providing technical information relating to an electrical component, the method comprising:
obtaining technical information associated with each of one or more parameters of the electrical component; and
upon a user selecting one of the parameters by providing user input to a graphical user interface, displaying on the graphical user interface the technical information associated with the selected parameter.

9. The method of claim 8, wherein the technical information identifies other parameters upon which the selected parameter depends.

10. A computer implemented method of identifying corresponding electrical component information in response to a received user input, the method comprising:
obtaining data associating one or more pins of an electrical component with pins of two or more corresponding representations of the electrical component displayed on a graphical user interface generated by a computer system; and
identifying, when a user provides data input to the graphical user interface to select a pin in one of the representations of the electrical component, and an associated pin in the at least one other representation.

11. The method of claim 10, wherein one of the representations of the electrical component is a graphical representation of the electrical component as a symbol or a diagram.

12. The method of claim 10, wherein one of the representations of the electrical component is data in a table.

13. A computer-readable storage medium containing instructions that, when executed, cause a computer to perform the method of claim 1.

14. A computer-readable storage medium containing instructions that, when executed, cause a computer to perform the method of claim 8.

15. A computer-readable storage medium containing instructions that, when executed, cause a computer to perform the method of claim 10.

16. An information processing apparatus for interactive display of electrical properties of an electrical component, the information processing apparatus comprising:
a processor and a data storage device storing program instructions operative to cause the processor to perform the method of claim 1.

17. An information processing apparatus for interactive display of electrical properties of an electrical component, the information processing apparatus comprising:
a processor and a data storage device storing program instructions operative to cause the processor to perform the method of claim 8.

18. An information processing apparatus for interactive display of electrical properties of an electrical component, the information processing apparatus comprising: a processor and a data storage device storing program instructions operative to cause the processor to perform the method of claim 10.
